(19) United States
(12) Patent Application Publication
(10) Pub. No.: US 2024/0204092 A1
(43) Pub. Date: Jun. 20, 2024

(54) SEMICONDUCTOR DEVICE AND METHOD OF MANUFACTURING THE SAME

(71) Applicant: Samsung Electronics Co., Ltd., Suwon-si (KR)

(72) Inventors: Junhyuk PARK, Suwon-si (KR); Jaejoon OH, Suwon-si (KR); Sunkyu HWANG, Suwon-si (KR); Boram KIM, Suwon-si (KR); Jongseob KIM, Suwon-si (KR); Joonyong KIM, Suwon-si (KR)

(73) Assignee: Samsung Electronics Co., Ltd., Suwon-si (KR)

(21) Appl. No.: 18/321,284

(22) Filed: May 22, 2023

(30) Foreign Application Priority Data
Dec. 20, 2022 (KR) 10-2022-0179737

(51) Int. Cl. H01L 29/778; H01L 23/31; H01L 29/20; H01L 29/66

(52) U.S. Cl. CPC H01L 29/7786; H01L 23/3171; H01L 29/2003; H01L 29/66462

(57) ABSTRACT

A semiconductor device includes a channel layer, a lower barrier layer on the channel layer and including first impurities, an upper barrier layer arranged on the lower barrier layer and including second impurities having a concentration greater than a concentration of the first impurities, a gate electrode on the upper barrier layer, a gate semiconductor layer between the upper barrier layer and the gate electrode, and a source and a drain that are on the channel layer and are spaced apart from each other.

### CROSS-REFERENCE TO RELATED APPLICATION

This application is based on and claims priority under 35 U.S.C. § 119 to Korean Patent Application No. 10-2022-0179737, filed on Dec. 20, 2022, in the Korean Intellectual Property Office, the disclosure of which is incorporated by reference herein in its entirety.

### BACKGROUND

Various example embodiments relate to a semiconductor device and/or a method of manufacturing the same.

Various power conversion systems require devices controlling the flow of current through ON/OFF switching, for example, power devices. In a power conversion system, the efficiency of a power device may influence the efficiency of the entire system.

As a switching device, a metal oxide semiconductor field effect transistor (MOSFET) using silicon and/or an insulated gate bipolar transistor (IGBT) have been mainly used, but there may be a limit to increasing the efficiency of the switching device due to the material limitations of silicon. As an attempt to overcome the material limitations of silicon, research on a high electron mobility transistor (HEMT) using a heterojunction structure of a compound semiconductor has been actively conducted.

### SUMMARY

Various example embodiments provide a semiconductor device that may be used as a switching device with improved dynamic on-resistance (Dynamic Rₒₙ).

Alternatively or additionally, various example embodiments provide a method of manufacturing a semiconductor device that may be used as a switching device with improved dynamic on-resistance (Dynamic Rₒₙ).

Additional aspects will be set forth in part in the description which follows and, in part, will be apparent from the description, and/or may be learned by practice of variously presented example embodiments.

According to some example embodiments, a semiconductor device includes a channel layer, a lower barrier layer on the channel layer and including first impurities, an upper barrier layer on the lower barrier layer and including second impurities at a greater concentration than a concentration of the first impurities, a gate electrode on the upper barrier layer, a gate semiconductor layer between the upper barrier layer and the gate electrode, and a source and a drain on the channel layer and spaced apart from each other.

Alternatively or additionally, according to some example embodiments, a semiconductor device includes a channel layer, a lower barrier layer on the channel layer and including first impurities, an upper barrier layer on the lower barrier layer and including second impurities having a greater concentration than a concentration of the first impurities, a gate electrode on the upper barrier layer, a gate semiconductor layer between the upper barrier layer and the gate electrode, and a source and a drain on the channel layer and spaced apart from each other. The lower barrier layer defines a recess, and a thickness of a portion of the lower barrier layer that is closer to the gate electrode is less than a thickness of an edge portion of the lower barrier layer.

Alternatively or additionally according to some example embodiments, a method of manufacturing a semiconductor device includes sequentially forming a channel layer, a lower barrier layer, an upper barrier layer, and a gate semiconductor layer on a substrate, etching the upper barrier layer and the gate semiconductor layer, forming a gate electrode on the gate semiconductor layer, and forming a source and a drain respectively being in contact with both sides of the channel layer. The forming of the lower barrier layer and the upper barrier layer includes making a concentration of second impurities in the upper barrier layer be greater than a concentration of first impurities in the lower barrier layer.

### BRIEF DESCRIPTION OF THE DRAWINGS

The above and other aspects, features, and advantages of certain example embodiments will be more apparent from the following description taken in conjunction with the accompanying drawings, in which:

FIG. 1 is a cross-sectional view of a semiconductor device according to various example embodiments;

FIGS. 2A and 2B are cross-sectional views of a structure of a semiconductor device according to various example embodiments, respectively illustrating an off state and an on state;

FIG. 3 is a cross-sectional view of a semiconductor device according to another embodiment;

FIGS. 4A to 4D are diagrams illustrating a method of manufacturing the semiconductor device of FIGS. 2A and 2B, according to various example embodiments; and

FIGS. 5A to 5C are diagrams illustrating a method of manufacturing the semiconductor device of FIG. 3, according to another embodiment.

### DETAILED DESCRIPTION

Reference will now be made in detail to various embodiments, examples of which are illustrated in the accompanying drawings, wherein like reference numerals refer to like elements throughout. In this regard, example embodiments may have different forms and should not be construed as being limited to the descriptions set forth herein. Accordingly, various embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and/or a method of manufacturing the same are described more fully with reference to the accompanying drawings. Like reference numerals in the drawings denote like elements, and thus their description will be omitted. Sizes of components in the drawings may be exaggerated for convenience of explanation. Also, examples may be embodied in many different forms and should not be construed as being limited to the specific example embodiments set forth herein.

Hereinafter, in the case where an item is described as being “on˜” or “on top of˜” another item, the item may be directly on top of the other item, or the item may be on top of the other item without contact. An expression used in the singular encompasses the expression of the plural, unless it has a clearly different meaning in the context. Also, when any one portion is described as “including” a component, this means that other components may be further included without excluding other components unless otherwise stated.

The use of the terms “a” and “an” and “the” and similar referents in the context of describing the disclosure are to be construed to cover both the singular and the plural. Also, the steps of all methods described herein can be performed in any suitable order unless otherwise indicated herein or otherwise clearly contradicted by context.

Connections of lines or connecting members between components shown in the drawings are examples of functional connections and/or physical or circuit connections. In actual devices, alternative and/or additional various functional, physical, and/or circuit connections may be presented.

The use of all examples or example terms is simply for explaining technical ideas in detail, and the scope is not limited by these examples or exemplary terms unless limited by the claims.

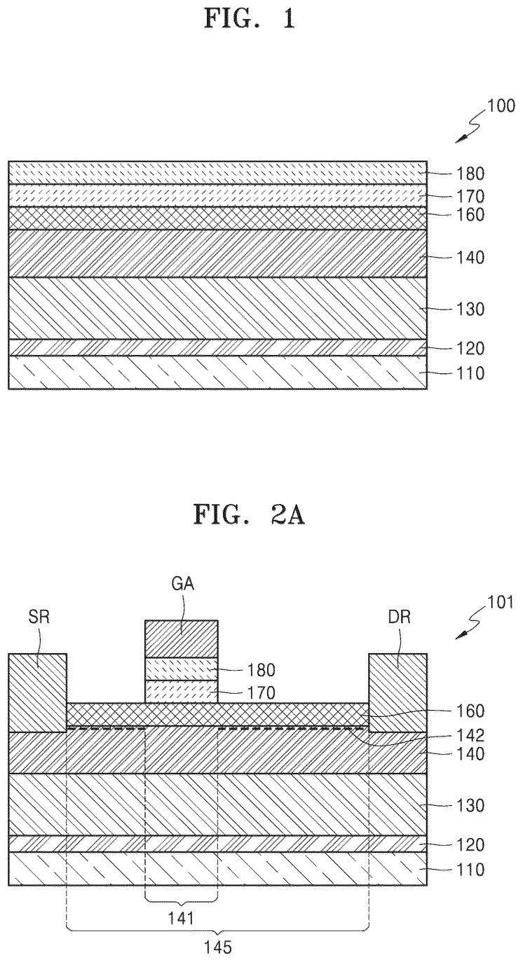

FIG. 1 is a cross-sectional view illustrating a schematic structure of a semiconductor device 100 according to various example embodiments.

The semiconductor device 100 may be used as or may include or correspond to a high electron mobility transistor (HEMT). An HEMT includes semiconductor layers having different electrical polarization characteristics. In an HEMT, a semiconductor layer having a relatively large polarizability may induce a 2-dimensional electron gas (2DEG) in another semiconductor layer heterojunction therewith. The 2DEG may be used as a channel between a drain electrode and a source electrode, and a current flowing through this channel is controlled by a bias voltage applied to a gate electrode.

Referring to FIG. 1, the semiconductor device 100 may include a channel layer 140, a lower barrier layer 160, an upper barrier layer 170, and a gate semiconductor layer 180. A seed layer 120 and a buffer layer 130 may be sequentially provided on a substrate 110, and the channel layer 140 may be formed on the buffer layer 130.

The substrate 110 may include, for example, one or more of sapphire (AlOx), silicon (Si), silicon carbide (SiC), gallium nitride (GaN), or the like. The buffer layer 130 may be formed above the substrate 110. The seed layer 120 may be provided between the substrate 110 and the buffer layer 130. The seed layer 120 may be or may correspond to a base layer for growing (e.g., epitaxially growing) the buffer layer 130. The substrate 110, the seed layer 120, and the buffer layer 130 are layers used as needed or used in a manufacturing process, and may be removed from the semiconductor device 100 in a final structure operating as an HEMT.

The buffer layer 130 may reduce a difference in lattice constants and/or thermal expansion coefficients between the substrate 110 and the channel layer 140, so as to prevent or reduce the likelihood of deterioration of the crystallinity of the channel layer 140. The buffer layer 130 may have a single-layered structure or multi-layered structure including one or more materials selected from among group III-V materials, for example, nitrides containing at least one of Al, Ga, and In. The buffer layer 130 may be or may include AlₓIn_{y}Ga_{1-x-y}N (0≤x≤1, 0≤y≤1, x+y≤1). The buffer layer 130 may have a single-layered structure or multi-layered structure including, for example, at least one of AlN, GaN, AlGaN, InGaN, AlInN, and AlGaInN.

The channel layer 140 is or includes or corresponds to a layer forming a channel between a source and a drain, and the channel layer 140 may include a material capable of forming a 2DEG therein. The channel layer 140 may include a single-layered structure or multi-layered structure including one or more materials selected from among group III-V materials, for example, nitrides containing at least one of Al, Ga, and In. The channel layer 140 may include AlₓIn_{y}Ga_{1-x-y}N (0≤x≤1, 0≤y≤1, x+y≤1). For example, the channel layer 140 may include at least one of AlN, GaN, InN, InGaN, AlGaN, AlInN, AlInGaN, or the like. The channel layer 140 may be or may include an undoped layer or a layer doped with impurities. A thickness of the channel layer 140 may be several hundreds of nm or less.

The lower barrier layer 160 may be arranged on the channel layer 140. The lower barrier layer 160 may include a semiconductor material different from that of the channel layer 140. The lower barrier layer 160 may differ from the channel layer 140 in at least one of a polarization characteristic, an energy bandgap, and a lattice constant. The lower barrier layer 160 may have a single-layered structure or multi-layered structure including one or more materials selected from among nitrides containing at least one of Al, Ga, and In. The lower barrier layer 160 may include Al_{y}Ga_{1-y}N (0≤y≤1). For example, the lower barrier layer 160 may include AlGaN.

The lower barrier layer 160 may be doped with a certain impurity. The impurity may be an acceptor capable of providing a hole (or, accepting an electron). The acceptor may be or may include an element that, when activated in a lattice such as a semiconductor lattice, forms a p-type region. In some example embodiments, the acceptor impurity may be or may include an element from group III of the periodic table. However, example embodiments are not limited thereto, and alternatively or additionally in some example embodiment the acceptor impurity may be or may include an element from either or both of group II and group IV of the periodic table.

A first acceptor doped in the lower barrier layer 160 may be doped at a lower concentration than a second acceptor doped in the upper barrier layer 170. The first acceptor doped in the lower barrier layer 160 may have a deeper energy level than the second acceptor doped in the upper barrier layer 170. The first acceptor doped the lower barrier layer 160 may be deeper with respect to an upper surface of the lower barrier layer 160 than, e.g. may have a peak concentration deeper with respect to an upper surface of the lower barrier 160 than that of the second acceptor doped in the upper barrier layer 170. The first acceptor doped in the lower barrier layer 160 may have, for example, an energy level of about 0.5 eV or more and about 1.0 eV or less. The lower barrier layer 160 may be doped with, for example, carbon (C).

The lower barrier layer 160 may have a semi-insulating characteristic having higher resistance than that of a general semiconductor. The occurrence of traps, such as electron and/or hole traps, may be suppressed or at least partly suppressed by the semi-insulating characteristic of the lower barrier layer 160 to improve a dynamic on-resistance characteristic (Dynamic Rₒₙ) of a device.

The upper barrier layer 170 may be arranged on the lower barrier layer 160. The upper barrier layer 170 may include a semiconductor material different from that of the channel layer 140. The upper barrier layer 170 may differ from the channel layer 140 in at least one of a polarization characteristic, an energy bandgap, and a lattice constant. The upper barrier layer 170 may have a multi-layered structuring including one or more materials selected from among nitrides containing at least one of Al, Ga, and In. For example, the upper barrier layer 170 may include AlGaN.

The upper barrier layer 170 may be doped with a certain impurity. The impurity may be an acceptor capable of providing a hole. The second acceptor doping the upper barrier layer 170 may be doped at a higher concentration than the first acceptor doping the lower barrier layer 160. The second acceptor doped in the upper barrier layer 170 may have a shallower energy level than the first acceptor doped in the lower barrier layer 160. The upper barrier layer 170 doped in the first acceptor may have, for example, an energy level greater than 0 eV and about 0.4 eV or less. The upper barrier layer 170 may be doped with, for example, magnesium (Mg).

The lower barrier layer 160 may include Al_{y}Ga_{1-y}N (0≤y≤1), and the upper barrier layer 170 may include AlₓGa₁₋ₓN (0≤x≤1). An aluminum (Al) concentration of the upper barrier layer 170 may be less than an Al concentration of the lower barrier layer 160. That is, x may be less than y.

Although each of the lower barrier layer 160 and the upper barrier layer 170 is shown as one layer, each of the lower barrier layer 160 and the upper barrier layer 170 may include a plurality of layers. Each of the lower barrier layer 160 and the upper barrier layer 170 may include a plurality of layers having the same or different Al concentrations, that may increase, decrease, or both increase and decrease at different levels. An Al concentration of each of or at least one of or the majority of the plurality of layers of the lower barrier layer 160 may be greater than an Al concentration of each of or at least one of or the majority of the plurality of layers of the upper barrier layer 170. Alternatively or additionally, the plurality of layers of the lower barrier layer 160 may be arranged such that a layer close to the channel layer 140 among the plurality of layers of the lower barrier layer 160 has a higher Al concentration, and a plurality of layers of the upper barrier layer 170 may be arranged such that a layer close to the channel layer 140 among the plurality of layers of the upper barrier layer 170 has a higher Al concentration. For example, the Al concentration in the lower barrier layer 160 or the upper barrier layer 170 may gradually increase toward the channel layer 140. The lower barrier layer 160 and/or the upper barrier layer 170 may include a plurality of layers so that the aluminum concentration thereof changes discontinuously, but may also include a layer in which the Al concentration is continuously varied.

The gate semiconductor layer 180 may be arranged on the upper barrier layer 170. The gate semiconductor layer 180 may be a or may include p-type semiconductor, e.g. a semiconductor device doped with p-type impurities. The gate semiconductor layer 180 may include one or more materials selected from among group III-V materials, for example, nitrides containing at least one of Al, Ga, and In. The gate semiconductor layer 180 may be or may include AlₓIn_{y}Ga_{1-x-y}N (0≤x≤1, 0≤y≤1, x+y≤1). The gate semiconductor layer 180 may include at least one of GaN, InN, AlGaN, AlInN, InGaN, AlN, AlInGaN, or the like. The gate semiconductor layer 180 may be doped with a p-type impurity, such as Mg. For example, the gate semiconductor layer 180 may include p-type GaN. However, example embodiments are not limited thereto, and the gate semiconductor layer 180 may be a p-AlGaN layer.

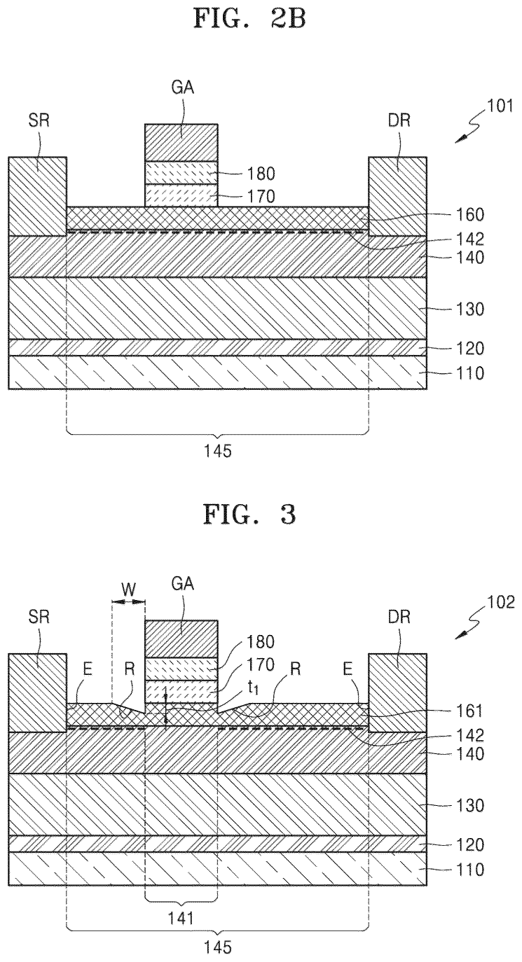

FIGS. 2A and 2B are cross-sectional views of a schematic structure of a semiconductor device according to various example embodiments, respectively illustrating an off state and an on state.

Referring to FIGS. 2A and 2B, a semiconductor device 101 may include the channel layer 140, the lower barrier layer 160, the upper barrier layer 170, the gate semiconductor layer 180, a gate electrode GA, a source SR, and a drain DR. As various example embodiments, the seed layer 120 and the buffer layer 130 may be sequentially provided on the substrate 110, and the channel layer 140 may be formed on the buffer layer 130. In the description of FIGS. 2A and 2B, redundant descriptions of FIG. 1 are omitted.

A region of the channel layer 140, e.g. the region facing the lower barrier layer 160, may become a drift region 145. The drift region 145 is a region formed in the channel layer 140 between the source SR and the drain DR, and corresponds to a region where carrier movement occurs when a potential difference is generated between the source SR and the drain DR. As described below, the carrier movement of the drift region 145 may be adjusted according to whether a voltage is applied to the gate electrode GA and/or the magnitude and/or sign of a voltage applied to the gate electrode GA.

The lower barrier layer 160 may have a higher electrical polarizability than the channel layer 140. Accordingly, a 2DEG 142 may be induced in the channel layer 140 having a relatively low electrical polarizability by the lower barrier layer 160. In this regard, the lower barrier layer 160 may be referred to as a channel supply layer or a 2DEG supply layer. The 2DEG 142 may be formed in the region of the channel layer 140, the region being below the interface between the channel layer 140 and the lower barrier layer 160. The 2DEG 142 exhibits very high electron mobility.

The upper barrier layer 170 and the gate semiconductor layer 180 may be etched, e.g. dry etched and/or wet etched, to have the same width as the gate electrode GA to be formed. Because the upper barrier layer 170 and the gate semiconductor layer 180 are etched, each of the width of the upper barrier layer 170 and the width of the gate semiconductor layer 180 is less than the width of the lower barrier layer 160. The upper barrier layer 170 and the gate semiconductor layer 180 may be respectively the same as the upper barrier layer 170 and the gate semiconductor layer 180 of FIG. 1 except a point of being etched.

The source SR and the drain DR may be formed to be spaced apart from each other on the channel layer 140. The source SR may be formed on one side of the channel layer 140 to be electrically connected to the channel layer 140, and the drain DR may be formed on another side of the channel layer 140 to be electrically connected to the channel layer 140. The source SR and the drain DR may each be formed outside the drift region 145 on the channel layer 140. The source SR and the drain DR may each make contact, e.g. linear or ohmic contact with the channel layer 140. The source SR and the drain DR may each include an electrically conductive material. The source SR and the drain DR may each include, for example, a metal material (e.g. the same and/or different metal materials). Regions of the channel layer 140 where the source SR and the drain DR are in contact thereto may be doped at a higher concentration than other regions of the channel layer 140. The 2DEG 142 formed in the channel layer 140 may be used as a current passage between the source SR and the drain DR, that is, a channel.

The gate semiconductor layer 180 may be on the upper barrier layer 170. The gate semiconductor layer 180 may be positioned between the source SR and the drain DR to be spaced apart from the source SR and the drain DR. The gate semiconductor layer 180 may be positioned closer to the source SR than the drain DR. The gate semiconductor layer 180 may have a different energy bandgap from that of the upper barrier layer 170.

The gate semiconductor layer 180 may form a depletion region 141 in the channel layer 140, e.g. during operation of the semiconductor device 101. Due to the gate semiconductor layer 180, the energy band level of a partial region of the lower barrier layer 160 at a position facing the gate semiconductor layer 180 may increase. Due to the gate semiconductor layer 180, the depletion region 141 may be formed in a region of the channel layer 140, the region facing the partial region of the lower barrier layer 160 having the increased energy band level. The depletion region 141 is or corresponds to a region in the channel path of the channel layer 140 where the 2DEG 142 is not formed or has a lower electron concentration than other regions. For example, due to the depletion region 141, the 2DEG 142 is disconnected. Accordingly, current does not flow between the source SR and the drain DR, and the channel path may be blocked.

The semiconductor device 101 may be or may include or be included in an HEMT having a normally off characteristic. According to the normally off characteristic, in a gate off state, that is, in a normal state in which a voltage is not applied to the gate electrode GA, as shown in FIG. 2A, a channel is in an off state and when a voltage is applied to the gate electrode GA, a channel is formed by the 2DEG 142 and is in an on state. When a voltage greater than a threshold voltage is applied to the gate electrode GA, instead of the depletion region 141 of FIG. 2A, as shown in FIG. 2B, the 2DEG 142 is formed on the entire channel path between the source SR and the drain DR, and the channel is in an on state.

The gate electrode GA may be formed on the gate semiconductor layer 180. The gate electrode GA may make linear or ohmic contact with the gate semiconductor layer 180. The gate electrode GA may include an electrically conductive material, for example, a metal material. When no voltage is applied to the gate electrode GA, the depletion region 141 is formed in the channel layer 140, and the channel is not formed by the 2DEG 142. A state shown in FIG. 2A is an off state in which no current flows from the source SR to the drain DR. When a voltage greater than a threshold voltage is applied to the gate electrode GA, the concentration of the 2DEG 142 increases in a region of the region of the channel layer 140, the region facing the gate semiconductor layer 180, and the range of the 2DEG 142 is extended, so that the depletion region 141 disappears and a channel is formed. A state shown in FIG. 2B is an on state in which current flows from the source SR to the drain DR.

In the semiconductor device 101 of various example embodiments, the gate semiconductor layer 180 may be provided appropriately for the normally off characteristic as described above, and also, a detailed configuration may be determined so as to reduce gate leakage current.

The gate semiconductor layer 180 may have a thickness of, for example, about 2 nm or more and about 200 nm or less. The gate semiconductor layer 180 may have a thickness of, for example, about 10 nm or more and about 200 nm or less. The thickness of the gate semiconductor layer 180 may be appropriately determined for a normally off characteristic. When the thickness of the gate semiconductor layer 180 is less than a certain amount, the depletion region 141 is not formed in the channel layer 140, and a normally on characteristic in which current flows in an off state may appear. When the thickness of the gate semiconductor layer 180 exceeds a certain amount, the energy band level of a region of the upper barrier layer 170 at a position facing the gate semiconductor layer 180 may become excessively high, and a bias voltage applied to the gate electrode GA may become excessively high to set an HEMT to an on state.

FIG. 3 is a cross-sectional view illustrating a schematic structure of a semiconductor device 102 according to another embodiment.

Referring to FIG. 3, the semiconductor device 102 may include the channel layer 140, a lower barrier layer 161, the upper barrier layer 170, the gate semiconductor layer 180, the gate electrode GA, the source SR, and the drain DR. As various example embodiments, the seed layer 120 and the buffer layer 130 may be sequentially provided on the substrate 110, and the channel layer 140 may be formed on the buffer layer 130. In the description of FIG. 3, redundant descriptions of FIGS. 1 to 2B are omitted.

The upper barrier layer 170 and the gate semiconductor layer 180 may be etched to have the same width as the gate electrode GA to be formed. The upper barrier layer 170 and the gate semiconductor layer 180 may be respectively the same as the upper barrier layer 170 and the gate semiconductor layer 180 of FIG. 1 except a point of being etched.

A portion of the lower barrier layer 161 may be etched together when the upper barrier layer 170 and the gate semiconductor layer 180 are etched. The lower barrier layer 161 may be etched to form or define a recess R. The lower barrier layer 161 may be etched to have a thickness decreasing toward the gate electrode GA. The lower barrier layer 161 may be etched to have a thickness linearly decreasing toward the gate electrode GA, and/or may have a thickness which is non-linearly decreased. A thickness of a portion of the lower barrier layer 161, the portion being close or closest to the gate electrode GA, may be less than a thickness of an edge portion E of the lower barrier layer 161. The thickness of the lower barrier layer 161 may be reduced by having the recess R. The recess R of the lower barrier layer 161 may have a depth of about 1 nm or more and about 20 nm or less. The thickness of the lower barrier layer 161 may be reduced by about 1 nm or more and about 20 nm or less. For example, t₁ may be about 1 nm or more and about 20 nm or less. The thickness of the lower barrier layer 161 may be reduced from a point away from the gate electrode GA by about 1 nm or more and about 1000 nm or less. In other words, a width W of the recess R may be about 1 nm or more and about 1000 nm or less from the gate electrode GA to the point where the thickness of the lower barrier layer 161 starts to reduce. The lower barrier layer 161 may be the same as the lower barrier layer 160 of FIGS. 1 to 2B except that the thickness thereof may decrease toward the gate electrode GA.

The lower barrier layer 161 may have the recess R at a portion of the gate electrode GA to reduce the 2DEG near the gate electrode GA, and accordingly, an electric field relaxation effect may be obtained, and a turn-on voltage of a device may also be adjusted.

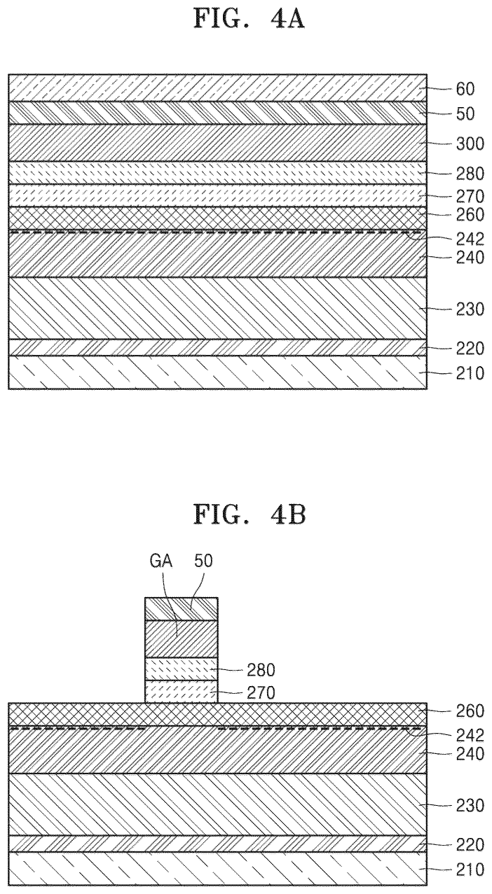

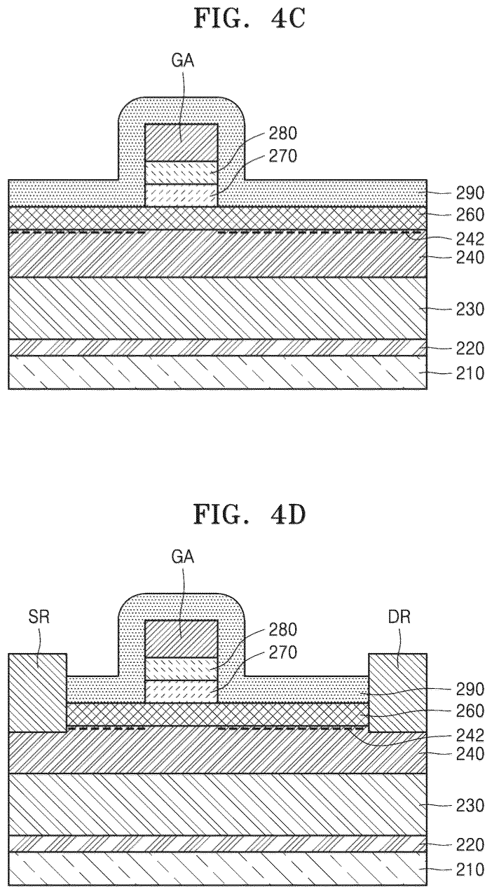

FIGS. 4A to 4D are diagrams for explaining a method of manufacturing a semiconductor device according to various example embodiments.

Referring to FIG. 4A, a channel layer 240, a lower barrier layer 260, an upper barrier layer 270, a gate semiconductor layer 280, and a gate electrode material layer 300 are sequentially formed on a substrate 210, and may be formed with one or more processes such as one or more chemical vapor deposition (CVD) processes and/or atomic layer deposition (ALD) processes. The upper barrier layer 270 may be formed to include a second acceptor impurity having a higher concentration and a shallower level or shallower energy level than a first acceptor impurity of the lower barrier layer 260. A seed layer 220 and a buffer layer 230 may be formed between the substrate 210 and the channel layer 240. The first acceptor impurities and/or the second acceptor impurities may be implanted and/or may be incorporated during a deposition process. The channel layer 240 may include a 2DEG 242 induced by the lower barrier layer 260. The materials of the substrate 210, the seed layer 220, the buffer layer 230, the channel layer 240, the lower barrier layer 260, the upper barrier layer 270, the gate semiconductor layer 280, and the gate electrode material layer 300 may respectively use the materials associated with respect to the substrate 110, the seed layer 120, the buffer layer 130, the channel layer 140, the lower barrier layer 160, the upper barrier layer 170, the gate semiconductor layer 180, and the gate electrode GA described above.

A hard mask layer 50 and a photoresist layer 60 May be formed on the gate electrode material layer 300. Through a photolithography process using the photoresist layer 60, the hard mask layer 50 May be patterned to fit the width of a gate electrode to be formed. The gate electrode material layer 300, the gate semiconductor layer 280, and the upper barrier layer 270 may be etched by using the patterned hard mask layer 50. Accordingly, the gate electrode GA may be formed, as shown in FIG. 4B.

Referring to FIG. 4C, a passivation layer 290 covering the lower barrier layer 260, the upper barrier layer 270, the gate semiconductor layer 280, and the gate electrode GA may be formed. The passivation layer 290 may include various types of insulating materials, for example, oxides such as one or more of SiO₂, HfOₓ, Al₂O₃, or the like.

Referring to FIG. 4D, the source SR and drain DR, each of which being in contact with the channel layer 240 by passing through the passivation layer 290, may be formed. The source SR and the drain DR may respectively be in contact with both sides of the channel layer 240.

A semiconductor device manufactured in this way may be substantially the same as the semiconductor device 101 described with reference to FIGS. 2A and 2B.

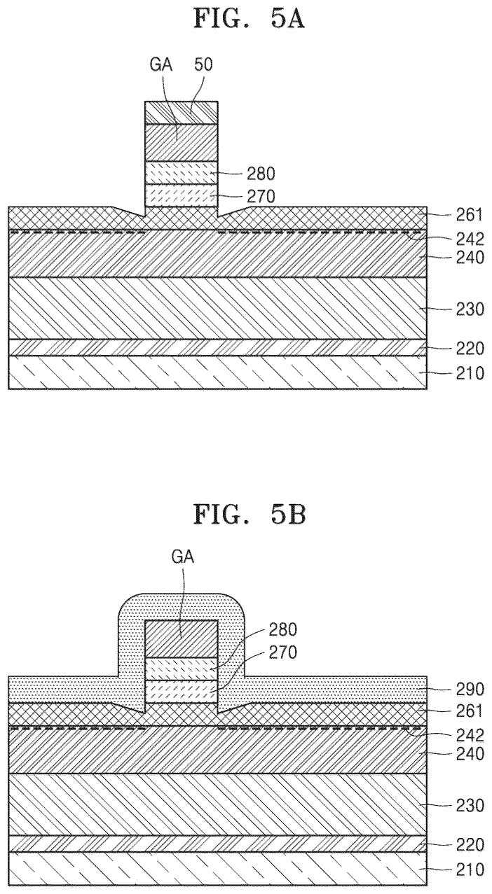

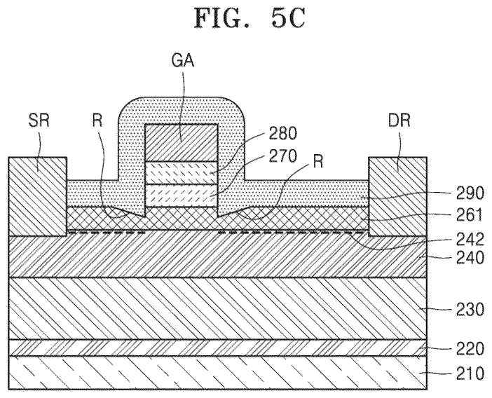

FIGS. 5A to 5C are diagrams for explaining a method of manufacturing a semiconductor device according to various example embodiments.

Operations in FIGS. 4B to 4D may be replaced with operations in FIGS. 5A to 5C.

Referring to FIG. 5A, the hard mask layer 50 and the photoresist layer may be formed on the gate electrode material layer. Through a photolithography process using the photoresist layer, the hard mask layer 50 May be patterned to fit the width of a gate electrode to be formed. The gate electrode material layer, the gate semiconductor layer 280, and the upper barrier layer 270 may be etched by using the patterned hard mask layer 50. Accordingly, the gate electrode GA may be formed, as shown in FIG. 5A.

When the gate electrode material layer, the gate semiconductor layer 280, and the upper barrier layer 270 are etched by using the hard mask layer 50, a portion of a lower barrier layer 261 may be etched together. The lower barrier layer 261 may be etched to form the recess R. The lower barrier layer 261 may be etched to have a thickness decreasing toward the gate electrode GA. The lower barrier layer 261 may be etched to have a thickness linearly decreasing toward the gate electrode GA, or may have a thickness which is non-linearly and/or piecewise linearly decreased. A thickness of a portion of the lower barrier layer 261, the portion being close to the gate electrode GA, may be less than a thickness of the edge portion E of the lower barrier layer 261. The thickness of the lower barrier layer 261 may be reduced by having the recess R. The thickness of the lower barrier layer 261 may be reduced by about 1 nm or more and about 20 nm or less by having the recess R. The thickness of the lower barrier layer 261 may be reduced from a distance away from the gate electrode GA by about 1 nm or more and about 1000 nm or less.

Referring to FIG. 5B, the passivation layer 290 covering the lower barrier layer 261, the upper barrier layer 270, the gate semiconductor layer 280, and the gate electrode GA is formed. The passivation layer 290 may include various types of insulating materials, for example, oxides such as SiO₂, HfOₓ, Al₂O₃, or the like.

Referring to FIG. 5C, the source SR and the drain DR, each of which being in contact with the channel layer 240 by passing through the passivation layer 290, are formed. The source SR and the drain DR may respectively be in contact with both sides of the channel layer 240.

A semiconductor device manufactured in this way may be substantially the same as the semiconductor device 102 described with reference to FIG. 3.

Accordingly, according to various example embodiments, it may be confirmed that a semiconductor device having improved dynamic Rₒₙ and/or a method of manufacturing the same may be provided.

The semiconductor device according to various example embodiments may be used as an HEMT device with improved dynamic Rₒₙ.

According to a method of manufacturing a semiconductor device according to various example embodiments, a semiconductor device in which upper and lower barrier layers have different acceptor dopant concentrations and/or Al concentrations may be provided.

It should be understood that various embodiments described herein should be considered in a descriptive sense only and not for purposes of limitation. Descriptions of features or aspects within each example embodiment should typically be considered as available for other similar features or aspects in other example embodiments, and example embodiments are not necessarily mutually exclusive with one another. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer;
a lower barrier layer on the channel layer and comprising first impurities;
an upper barrier layer on the lower barrier layer and comprising second impurities having a concentration greater than a concentration of the first impurities;
a gate electrode on the upper barrier layer;
a gate semiconductor layer between the upper barrier layer and the gate electrode; and
a source and a drain that are on the channel layer and are spaced apart from each other.

2. The semiconductor device of claim 1, wherein the second impurities are at shallower level with respect to a top of the upper barrier layer than a level of the first impurities with respect to a top of the lower barrier layer.

3. The semiconductor device of claim 1, wherein each of the upper barrier layer and the lower barrier layer comprises AlGaN.

4. The semiconductor device of claim 1, wherein the upper barrier layer comprises AlₓGa₁₋ₓN,
the lower barrier layer comprises Al_{y}Ga_{1-y}N, and
x is less than the y.

5. The semiconductor device of claim 1, wherein the lower barrier layer exhibits semi-insulating characteristics.

6. The semiconductor device of claim 1, wherein the first impurities comprises carbon, and the second impurities comprises magnesium.

7. The semiconductor device of claim 1, wherein the channel layer comprises a group III-V compound semiconductor.

8. The semiconductor device of claim 1, wherein the gate semiconductor layer comprises p-type GaN.

9. The semiconductor device of claim 1, further comprising:
a passivation layer surrounding the lower barrier layer, the upper barrier layer, the gate semiconductor layer, and the gate electrode.

10. The semiconductor device of claim 1, wherein the semiconductor device comprises a high electron mobility transistor having a normally off characteristic.

11. A semiconductor device comprising:
a channel layer;
a lower barrier layer on the channel layer and comprising first impurities;
an upper barrier layer on the lower barrier layer and comprising second impurities having a concentration greater than a concentration of the first impurities;
a gate electrode on the upper barrier layer;
a gate semiconductor layer between the upper barrier layer and the gate electrode; and
a source and a drain that are on the channel layer and are spaced apart from each other,
wherein the lower barrier layer defines a recess, and a thickness of a portion of the lower barrier layer that is close to the gate electrode is less than a thickness of an edge portion of the lower barrier layer.

12. The semiconductor device of claim 11, wherein a point where a thickness of the lower barrier layer decreases is about 1 nm or more and about 1,000 nm or less in a direction away from the gate electrode.

13. The semiconductor device of claim 11, wherein the recess has a depth of about 1 nm or more and about 20 nm or less.

14. The semiconductor device of claim 11, wherein the second impurities of the upper barrier layer are shallower with respect to a top of the upper barrier layer than a level of the first impurities with respect to a top of the lower barrier layer.

15. The semiconductor device of claim 11, wherein each of the upper barrier layer and the lower barrier layer comprises AlGaN.

16. The semiconductor device of claim 11, wherein an aluminum concentration of the upper barrier layer is less than an aluminum concentration of the lower barrier layer.

17. The semiconductor device of claim 11, wherein the lower barrier layer exhibits semi-insulating characteristics.

18. The semiconductor device of claim 11, wherein the first impurities comprise carbon, and the second impurities comprise magnesium.

19. The semiconductor device of claim 11, further comprising:
a passivation layer surrounding the lower barrier layer, the upper barrier layer, the gate semiconductor layer, and the gate electrode.

20. A method of manufacturing a semiconductor device, the method comprising:
sequentially forming a channel layer, a lower barrier layer, an upper barrier layer, and a gate semiconductor layer on a substrate;
etching the upper barrier layer and the gate semiconductor layer;
forming a gate electrode on the gate semiconductor layer; and
forming a source and a drain respectively being in contact with a first side of and a second side of the channel layer,
wherein the forming of the lower barrier layer and the upper barrier layer comprises making a concentration of a second impurity in the upper barrier layer be greater than a concentration of a first impurity in the lower barrier layer.
